(19) United States
(12) Patent Application Publication
(10) Pub. No.: US 2009/0312187 A1
(43) Pub. Date: Dec. 17, 2009

(54) Method for fabricating a superconducting wire

(75) Inventors: Masahiro Seido, Tsuchiura (JP); Katsumi Ohata, Tsuchiura (JP); Kazuhiko Nakagawa, Tsuchiura (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Hitachi Cable, Ltd., Tokyo (JP)

(21) Appl. No.: 12/453,237

(22) Filed: May 4, 2009

(30) Foreign Application Priority Data
Jun. 16, 2008 (JP) 2008-156441

(51) Int. Cl. H01L 39/24

(52) U.S. Cl. 505/431; 29/599

(57) ABSTRACT

A metallic thin film is wound around a core material made of a first metallic material in a predetermined number of windings to provide a first wire rod having a diameter which is applicable for roll forming in a longitudinal direction of the core material. The metallic thin film is formed by rolling a second metallic material and carrying out an annealing heat treatment on the rolled second metallic material. The first wire rod is cut to provide second wire rods, and the second wire rods are filled into a billet for multi-wires to provide a multi billet. The multi billet is extruded and drawn. Thereafter, a heat treatment is carried out on the drawn material to provide a superconducting wire.

The present application is based on Japanese Patent Application No. 2008-156441 filed on Jun. 16, 2008, the entire contents of which are incorporated herein by reference.

### BACKGROUND OF THE INVENTION

1. Field of the Invention

The present invention relates to a method for fabricating a superconducting wire, in more particular, to a method for fabricating a superconducting wire, by which the superconducting wire with a smaller diameter can be fabricated with high working efficiency.

2. Related Art

Conventionally, a metal based superconducting wire has been fabricated by using a fabrication method determined in accordance with characteristics of a material composing the superconducting wire. As an example of conventional methods for fabricating a superconducting wire comprising Nb₃Al based compound, a technique of fabricating a superconducting wire comprising preparing a jelly roll wire rod having a multilayer winding structure with several dozens of layers formed by winding a Nb sheet and an Al sheet together around a Nb core by a jelly rolling method, reducing a diameter of the jelly rod wire rod to provide a fine jelly roll wire, filling a plurality of fine jelly roll wires into a billet for multi-wires (multifilament) to provide a multi billet, drawing the multi billet by a hydrostatic pressure extrusion, carrying out a rapid heating and quenching treatment on the drawn wire, thereby providing a Nb₃Al based compound superconducting wire having a diameter of 60 μm or more has been known. For example, an article titled as “Transformation method for realizing long length” of National Institute for Materials Science (NIMS) searched on May 13, 2008, Internet (URL: http://www.nims.go.jp/smcMetal/Nb3Al_mitoh_{—}4.pdf) discloses an example of such a method.

According to the method for fabricating a superconducting wire described in the article of NIMS, since the multi billet is drawn by the hydrostatic pressure extrusion, it is possible to reduce a friction between the billet and tools, thereby realizing an extruding step at a low temperature.

However, there is a following disadvantage in the method for fabricating a superconducting wire disclosed in the article of NIMS. Since the number of layers of the Nb sheet and the Al sheet to be wound together around the Nb core by the jelly rolling method is large, it is difficult to reduce the wire diameter of the fabricated superconducting wire. Therefore, a fabrication process including numerous steps is further required for further reducing the wire diameter.

### SUMMARY OF THE INVENTION

Accordingly, an object of the present invention is to provide a method for fabricating a superconducting wire, by which a superconducting wire with small diameter can be fabricated with a high working efficiency.

According to a feature of the invention, a method for fabricating a superconducting wire comprises:

winding a metallic thin film around a core material comprising a first metallic material in a predetermined number of windings to provide a first wire rod having a diameter which is applicable for roll forming in a longitudinal direction of the core material, the metallic thin film being formed by rolling a second metallic material and carrying out an annealing heat treatment on the rolled second metallic material;

cutting the first wire rod to provide second wire rods;

filling the second wire rods into a billet for multi-wires to provide a multi billet;

extruding the multi billet to provide an extruded material;

drawing the extruded material to provide a drawn material; and

carrying out a heat treatment on the drawn material to provide the superconducting wire.

In the method for fabricating a superconducting wire, the superconducting wire may comprise Nb compound or Nb alloy, the first metallic material may comprise at least one metallic material selected from a group consisted of Nb, Nb alloy, Ta, Cu, Sn and Sn alloy, the second metallic material may comprise at least one metallic material selected from a group consisted of Nb, Sn, Sn alloy, Al and Cu, the first metallic material may comprise a material containing a first metal component composing the Nb compound, and a second metal component which forms the Nb compound by being bonded to the first metal component may be selected from components of the Nb compound as the second metallic material.

Alternatively, the first metallic material may comprise a material which does not contain a first metal component composing the Nb compound, and both of the first metal component and a second metal component which forms the Nb compound by being bonded to the first metal component may be selected from components of the Nb compound as the second metallic material.

In the method for fabricating a superconducting wire, metallic thin film tape may comprise a first tape comprising the first metal component and a second tape comprising the second metal component, and the first tape and the second tape may be wound together around the core.

The metallic thin film tape may comprise a composite tape of a first tape comprising the first metal component and a second tape comprising the second metal component.

In the method for fabricating a superconducting wire, the number of the second wire rods filled into the multi billet may be 1000 or more.

In the method for fabricating a superconducting wire, the predetermined number of windings may be 1.2 to 6 turns around the core material.

In the method for fabricating a superconducting wire, the second wire rods may be filled within a range of 0.2 to 0.4 pieces/mm² for a cross section of the billet for multi-wires.

### ADVANTAGES OF THE INVENTION

According to the method for fabricating a superconducting wire of the present invention, it is possible to provide a method for fabricating a superconducting wire, by which a superconducting wire with a smaller diameter can be fabricated with a high working efficiency.

### BRIEF DESCRIPTION OF THE DRAWINGS

Next, the preferred embodiment according to the invention will be explained in conjunction with appended drawings, wherein:

FIG. 1 is a flow chart showing a method for fabricating a superconducting wire in a preferred embodiment according to the present invention;

FIG. 2 is a schematic diagram showing a process for manufacturing an inner wire in Example 1 of the present invention;

FIG. 3 is a schematic diagram showing a process for manufacturing a wire rod in the Example 1 of the present invention;

FIG. 4 is a lateral cross sectional view of the wire rod in the Example 1 of the present invention; and

FIG. 5 it is a lateral cross sectional view of a multi billet in the Example 1 of the present invention.

### DETAILED DESCRIPTION OF THE PREFERRED EMBODIMENT

### Preferred Embodiment

Next, a preferred embodiment of the present invention will be explained in more detail in conjunction with appended drawings.

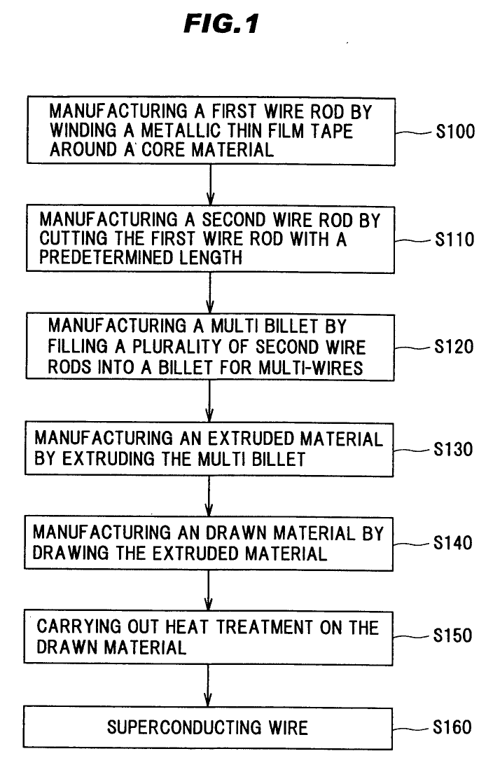

FIG. 1 is a flow chart showing a method for fabricating a superconducting wire in a preferred embodiment according to the present invention.

In the method for fabricating a superconducting wire in the preferred embodiment according to the present invention, a superconducting wire as a superfine multi-core superconducting wire is fabricated. In this preferred embodiment, the superconducting wire is fabricated by the jelly rolling method as an example. In addition, the superconducting wire fabricated by the method for fabricating a superconducting wire in this preferred embodiment may comprise a Nb compound or a Nb alloy such as a Nb₃Sn based compound material, a NbAl based compound material, and a Nb—Ti alloy based material.

At first, a core material comprising a predetermined first metallic material and a metallic thin film tape with a thin-film shape are prepared. The metallic thin film tape is selected in accordance with the superconducting wire to be fabricated, and the metallic thin film tape comprises a material including a second metallic material that is different from the first metallic material. The metallic thin film tape is fabricated by carrying out rolling processing on the second metallic material to have a predetermined thickness. Herein, as the metallic thin film tape, several kinds of metallic thin film tapes may be prepared in accordance with the superconducting wire to be fabricated. More concretely, in this preferred embodiment, the core material and one kind of the metallic thin film tape may be prepared, alternatively, the core material, one kind of the metallic thin film tape, and other kind(s) of the metallic thin film tape may be prepared in accordance with the superconducting wire to be fabricated.

The core material has a rod shape or a filament shape with a cross sectional diameter of several millimeters (mm) or less. The core material comprises a metallic material such as Nb, Nb alloy (e.g. Nb—Ti alloy), Ta, Cu, Sn, or Sn alloy as the first metallic material. On the other hand, the metallic thin film tape has a thin film shape with a thickness of about 100 μm or less. The metallic thin film tape comprises a metallic material such as Nb, Sn, Sn alloy, Al, or Cu as the second metallic material. For example, as the metallic thin film tape, a Nb tape, a Sn tape, a Sn alloy tape, an Al tape, a Cu tape, a composite tape of Nb tape/Sn alloy tape (e.g. for Nb₃Sn superconducting wire rod), a composite tape of Nb tape/Cu tape (e.g. for Nb₃Sn superconducting wire rod), or a composite tape of Nb tape/Al tape (e.g. for Nb₃Al superconducting wire rod) may be used in accordance with the superconducting wire to be fabricated.

Thereafter, the metallic thin film tape is wound (or wrapped) around the core material, to manufacture a first wire rod (FIG. 1: Step 100, hereinafter “Step” is abbreviated as “S”). More concretely, a composite tape is wound (or wrapped around the core, or several kinds of metallic thin film tapes are wound or wrapped together around the core, to provide the first wire rod. As an example of manufacturing the first wire rod by winding the composite tape around the core material, the first wire rod may be manufactured by winding the composite tape of Nb tape/Sn alloy tape around the core material. When winding several kinds of the metallic thin film tapes together, one metallic thin film tape and the other metallic thin film tape(s) may be wound together to be overlapped around the core material. As an example, the first wire rod may be manufactured by winding the Nb tape around the core, and thereafter winding the Sn alloy tape around the Nb tape. The first wire rod may be manufactured similarly to the above process, when other composite tape or other metallic thin film tapes are used. In addition, a predetermined metallic thin film tape (e.g. Cu tape) may be further wound around the first wire rod as an outermost layer, for the purpose of suppressing a fusion between respective second wire rods made from the first wire rod by carrying out the heat treatment after manufacturing the multi billet as described below.

TABLE 1 shows examples of combination of the first metallic material with the second metallic material in this preferred embodiment.

TABLE 1

| | Superconducting wire to be fabricated | | | | | |
|---|---|---|---|---|---|---|
| | | | | Nb₃Al | | Nb—Ti |
| | | | | superconducting | | superconducting |
| | Nb₃Sn superconducting wire rod | | | wire rod | | wire rod |
| Core material | Nb wire | Ta wire | Sn alloy wire | Nb wire | Ta wire | Nb—Ti wire |
| (First metallic | | or | | | | |
| material) | | Cu wire | | | | |

| | | | | |
|---|---|---|---|---|
| Metallic thin film | Composite tape of | Composite tape of | Composite tape of | Cu tape |
| tape | Nb tape/Sn alloy | Nb tape/Cu tape | Nb tape/Al tape | |
| (Second metallic | tape | or | or | |
| material) | or | Combination of | Combination of | |
| | Combination of | Nb tape and | Nb tape and | |
| | Nb tape and | Cu tape | Al tape | |
| | Sn alloy tape | | | |

Referring to TABLE 1, the case that the superconducting wire to be fabricated is the Nb₃Sn superconducting wire rod will be explained below as an example.

Firstly, when Nb (Nb wire) is selected as the core material comprising the first metallic material, it is necessary to select at least a metal thin film tape including Sn that is a component of the Nb₃Sn compound as the metallic thin film tape comprising the second metallic material. Sn is bonded with Nb in the first metallic material, thereby forming the Nb₃Sn compound. For example, at least the composite tape of Nb tape/Sn alloy tape or the Sn alloy tape may be selected.

When Ta (Ta wire) or Cu (Cu wire) is selected as the core material comprising the first metallic material, it is necessary to select at least a metal thin film tape including a component of the Nb₃Sn compound as the metallic thin film tape comprising the second metallic material. For example, the composite tape of Nb tape/Sn alloy tape or the combination of the Nb tape and the Sn alloy tape may be selected.

When Sn alloy (Sn alloy wire) is selected as the core material comprising the first metallic material, it is necessary to select at least a metal thin film tape including Nb that is a component of the Nb₃Sn compound as the metallic thin film tape comprising the second metallic material. Nb is bonded with Sn in the first metallic material, thereby forming the Nb₃Sn compound. For example, at least the composite tape of Nb tape/Cu alloy tape or the Nb tape should be selected.

In addition, for example, when the Nb tape is firstly wound around the core material and thereafter the Sn alloy tape is wound around the Nb tape, a barrier tape (e.g. Nb barrier tape) may be further wound around an outer periphery of the Sn alloy tape. Herein, when the Sn alloy tape is wound around the core and thereafter the Nb tape is wound around the Sn alloy tape, the barrier tape may be omitted. In other words, when the Sn alloy tape is wound around the core and thereafter the Nb tape is wound around the Sn alloy tape, the Nb barrier tape may be omitted.

In this preferred embodiment, the metallic thin film tape is wound around the core material in a predetermined number of windings to provide a diameter that falls within a predetermined range, for which roll forming can be carried out in a longitudinal direction of the core material. According to this process, a first wire rod having a small diameter and multiple windings is manufactured. More concretely, in this preferred embodiment, the metallic thin film tape is wound around the core material in 1.2 to 6 turns, thereby preparing the first wire rod.

Next, a plurality of second wire rods are manufactured by cutting the first wire rod with a predetermined length (S110).

For example, the first wire rod is cut in accordance with a length of a billet for multi-wires in a longitudinal direction, which will be explained later. Herein, an annealing heat treatment (annealing softening treatment) may be previously carried out for a predetermined time at a predetermined temperature under a predetermined atmosphere on the core material and/or the metallic thin film tape, or the first wire rod or the second wire rod before or after S100, or after S110, for the purpose of softening these materials.

By way of example only, the annealing heat treatment may be carried on the metallic thin film tape after preparing the core material and the metallic thin film tape in S100 and before manufacturing the first wire rod. In addition, when several kinds of the metallic thin film tapes are used, the annealing heat treatment under different conditions may be conducted on the respective metallic thin film tapes in accordance with the material composing each of the metallic thin film tapes.

Next, the plurality of second wire rods are filled into the billet for multi-wires to manufacture a multi billet (S120). In this preferred embodiment, the second wire rods are filled within a range of 0.2 to 0.4 pieces per sectional unit area of the billet for multi-wires (unit area is 1 mm²) as an example. Namely, the second wire rods are filled to satisfy the range of 0.2 to 0.4 pieces/mm² for a cross section of the billet for multi-wires. For example, the billet for multi-wires in this preferred embodiment comprises Cu and has a substantially cylindrical shape. In addition, when filling the second wire rods in the billet for multi-wires, a reaction-suppressing layer (barrier layer) comprising a high melting metallic material (e.g. Ta) may be further incorporated between the second wire rods and an inner wall of the billet for multi-wires. Herein, the annealing heat treatment may be carried on the reaction-suppressing layer before incorporating the reaction-suppressing layer in the billet for multi-wires, for the purpose of softening the reaction-suppressing layer.

Next, the multi billet is extruded by cold extruding or warm extruding to manufacture an extruded material (S130). In this preferred embodiment, the annealing heat treatment is carried on the second wire rods before filling the second wire rods into the billet for multi-wires, to soften the second wire rods by annealing. According to this process, it is possible to extrude the multi billet at a low temperature, namely, a temperature lower than a recrystallization temperature of the material composing the second wire rod, or at a room temperature.

Next, the extruded material is put into and drawn through a dice with a hole of a predetermined shape at the room temperature, to manufacture a drawn material with a predetermined diameter (S140).

Furthermore, heat treatment for a predetermined time at a predetermined temperature is carried out on the drawn material (S150).

According to this process, the superconducting wire in this preferred embodiment is fabricated (S160). In addition, the superconducting wire, in which a surface is jacketed with Cu as stabilizer after the heat treatment (S150), may be manufactured.

Both of Nb and Ta contained in the material of the superconducting wire in this preferred embodiment are materials in that a work hardening rate is high and a deformation resistance is large. On the other hand, Sn and Al are soft materials in that the work hardening rate is low. In addition, Cu to be used as the stabilizer has an intermediate strength between the metallic material such as Nb or the like and metallic material such as Sn or the like, and the work hardening of Cu is saturated earlier than those of Nb and Sn. Therefore, when a wire is formed by a single stack method with using a rod method from a composite material containing both of a material with a low work hardening rate (hereinafter, referred as to “low work hardening rate material”) and another material with a high work hardening rate (hereinafter, referred as to “high work hardening rate material”), the high work hardening rate material and the low work hardening rate material are processed by combined working.

For this case, since Sn or the like melts when the annealing heat treatment is carried out with a reference of the high melting material such as Ta, it is impossible to carry out the annealing heat treatment on the high work hardening rate material and the low work hardening rate material simultaneously, so that it is inevitable to carry out the annealing heat treatment only on the low work hardening rate material. Therefore, when the composite material comprises both of the high work hardening rate material and the low work hardening rate material and both of the materials are not softened, it is necessary to carry out the warm extrusion or hot extrusion for extruding the wire material comprising both of the high work hardening rate material and the low work hardening rate material. The Inventors found that characteristics of the superconducting wire to be fabricated are deteriorated as well as the workability is lowered when the above process is conducted.

For example, when the Nb—Ti alloy based material is used as a material of the wire rod, Nb—Ti precipitate and dislocations by the processing are generated, an artificial pinning center (APC) is introduced into the Nb—Ti alloy based material, thereby improving a high magnetic field property. In this case, the extrusion at a high temperature is required for manufacturing the wire rod from the Nb—Ti alloy based material, since this material is hard. However, the Nb—Ti alloy based material softens in the extruding processing at the high temperature. The Inventors found that the working efficiency of such an extruded material is decreased since the APC is not introduced into such an extruded material so that the extruding processing and the drawing processing in a large diameter should be repeatedly carried out until the APC is introduced. Furthermore, the Inventors found that manufacturing of the wire material may be disturbed by the melting of Sn, in the case that the Nb₃Sn based material, for example, is used and the warm processing or the hot processing is carried out on the Nb₃Sn based material.

However, in this preferred embodiment, it is possible to soften the high work hardening rate material and the low work hardening rate material by carrying out the annealing heat treatment previously to the high work hardening rate material and the low work hardening rate material, respectively. In other words, it is possible to use each of the high work hardening rate material and the low work hardening rate material composing the superconducting wire for fabricating the superconducting wire, with keeping a work hardening amount at a predetermined value or less. By way of example only, each of the core material comprising the first metallic material, the metallic thin film tape comprising the second metallic material, the stabilizer, and the reaction-suppressing layer may be used by previously carrying out the annealing heat treatment thereon. In addition, the annealing heat treatment can be carried out on each of the metallic thin film tapes when several kinds of the metallic thin film tapes are used.

Therefore, it is possible to extrude the wire material comprising both of the high work hardening rate material and the low work hardening rate material under a relatively low extruding pressure by the cold extrusion, thereby improving the working efficiency. For example, in this preferred embodiment, it is possible to extrude the multi billet incorporated with the second wire rod including Sn or Sn alloy without melting a region including Sn by a processing heat. According to this process, it is possible to fabricate the superconducting wire comprising the Nb₃Sn based material by e.g. the jelly rolling method at a high efficiency without disconnection.

### (Variations)

The method for fabricating the superconducting wire may be applied to other materials than the materials described above. For example, it is possible to fabricate the superconducting wire by using V₃Ga based compound material, MgB₂ based compound material, or oxide superconducting material such as Y based, Bi based, Tl based, Hg based, or Ag—Pb based oxide superconducting material.

### Effect of the Preferred Embodiment

According to the method for fabricating a superconducting wire in this preferred embodiment, the metallic thin film tape is formed by rolling processing, and the metallic thin film tape is wound around the outer periphery of the core material, so that it is possible to fabricate a small-sized first wire rod with high productivity. By way of example only, it is possible to fabricate the small-sized first wire rod having a small diameter after winding, by reducing the number of windings around the core material in addition to the use of the metallic thin film tape. Therefore, according to this preferred embodiment, it is possible to suppress an increase in production cost. Further, it is possible to manufacture a multi billet using 1000 pieces or more and around 5000 pieces of the second wire rod as an example. In other words, according to this preferred embodiment, it is possible to fabricate a superconducting wire in which an alternating current loss can be remarkably reduced.

Still further, according to the method for fabricating a superconducting wire in this preferred embodiment, the metallic thin film tape having the thin film shape is wound in several turns (layers) around the small diameter core material, so that it is possible to continuously fabricate the jelly roll wire rod as the first wire rod without disconnection by continuous roll forming and molding in the longitudinal direction. Thereafter, a predetermined number of the second wire rods made from the first wire rod are filled into the billet for multi-wires, and the multi billet filled with the second wire rods is formed to have a predetermined shape (e.g. hexagonal cross section), thereby forming the multi billet as a wire rod. According to the method for fabricating a superconducting wire in this preferred embodiment, it is possible to fabricate the superconducting wire with a small cross sectional area with a high yield, by remarkably reducing the working steps (i.e. remarkably improving the working efficiency).

In other words, according to the method for fabricating a superconducting wire in this preferred embodiment, it is possible to continuously manufacture the jelly roll wire rod as the first wire rod in which the metallic thin film tape is wound around the small diameter core material to the extent of several windings (layers) without disconnection. Further, it is possible to form the multi billet from the second wire rods made from the first wire rod and the billet for multi-wires by using the single stack method, thereby improving the productivity. Accordingly, it is possible to suppress the fabrication cost, and to fabricate the superconducting wire having the second wire rods as a plurality of superfine cores.

In this preferred embodiment, the first wire rod as a single superconducting wire rod is manufactured by winding the metallic thin film tape having the thin film shape in several turns around the small diameter core material. Thereafter, the second wire rods made from the first wire rod manufactured by using the single stack method are incorporated into the billet for multi-wires. The extruding processing and the drawing process are carried out on the billet for multi-wires, thereby manufacturing the superconducting wire having the predetermined diameter. Therefore, according to this preferred embodiment, it is possible to fabricate the superconducting wire with a stable magnetic field property and a reduced alternating current loss, which is suitable for practical use.

### Example 1

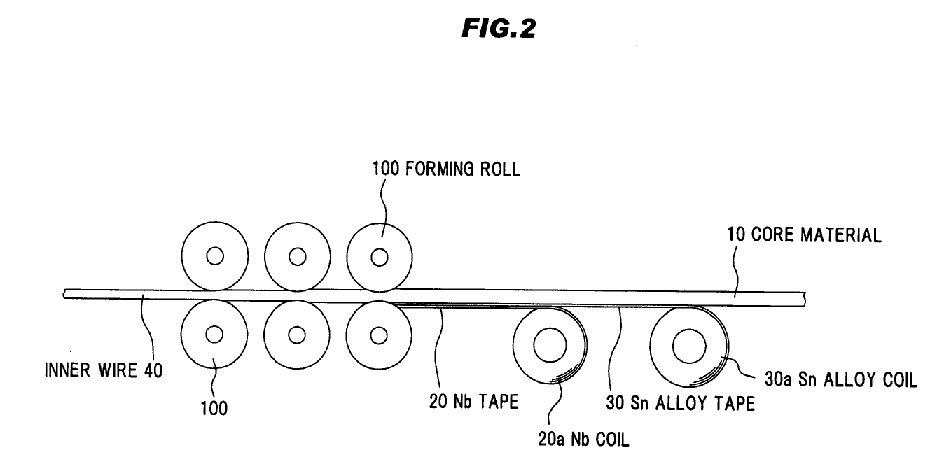

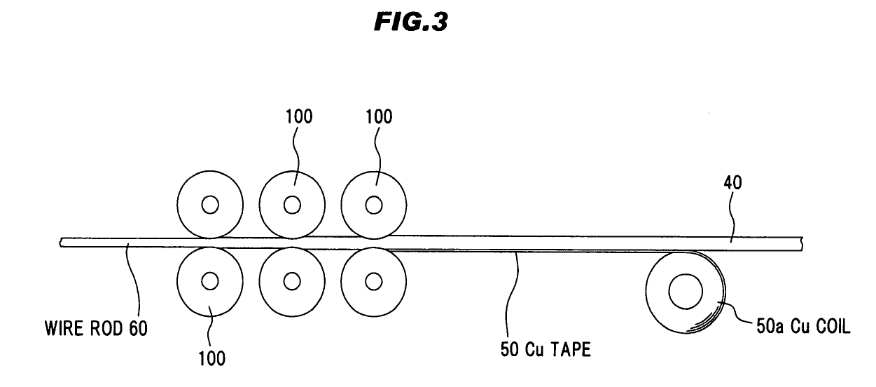

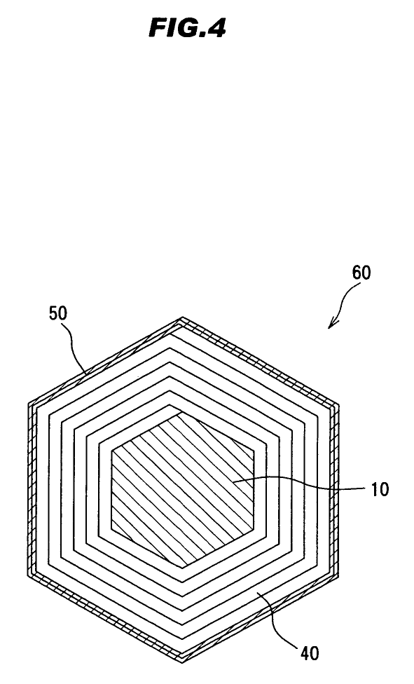

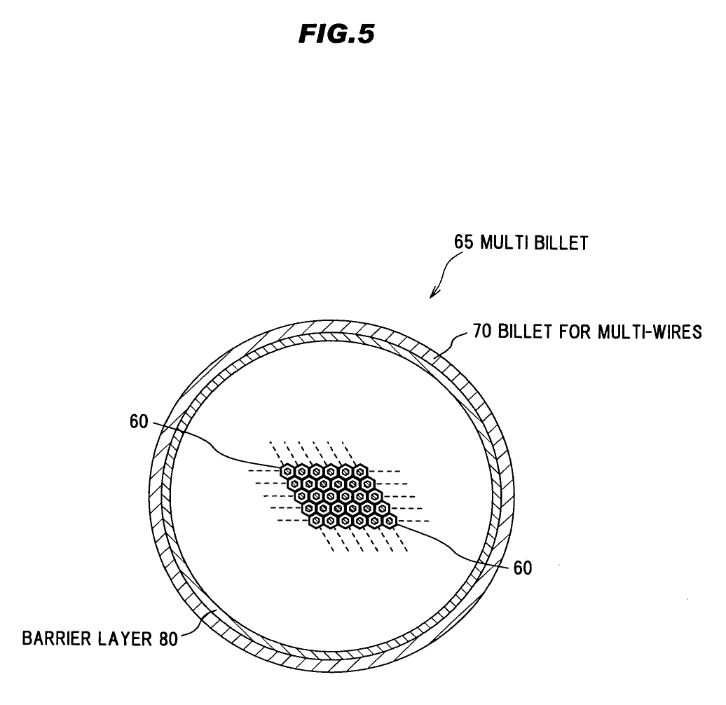

FIG. 2 is a schematic diagram showing a process for manufacturing an inner wire in Example 1 of the present invention. FIG. 3 is a schematic diagram showing a process for manufacturing a wire rod in the Example 1 of the present invention. FIG. 4 is a lateral cross sectional view of the wire rod in the Example 1 of the present invention. FIG. 5 it is a lateral cross sectional view of a multi billet in the Example 1 of the present invention.

In more concrete, Nb₃Sn was used as the material composing the superconducting wire in the Example 1 of the present invention. FIG. 2 shows an outline of a manufacturing process of an inner wire 40 by a continuous roll forming, and FIG. 3 shows an outline of a manufacturing process of a wire rod 60 as the first wire rod by continuous roll forming from the inner wire 40 fabricated in the process shown in FIG. 2.

Firstly, referring to FIG. 2, a Nb wire with a diameter of 0.8 mm was prepared as a core material 10 in the Example 1. A Sn alloy coil 30a, in which a Sn alloy tape 30 (thickness of 50 μm and a width of 15.1 mm) as the first metallic thin film tape was wound around a predetermined core, and a Nb coil 20a, in which a Nb tape 20 (thickness of 100 μm and a width of 15.1 mm) as the second metallic thin film tape was wound around a predetermined core, were prepared. The annealing heat treatment was previously carried out for a predetermined time at a predetermined temperature under a predetermined atmosphere on each of the core material 10, the Nb tape 20 and the Sn alloy tape 30. To be concrete, the annealing heat treatment was carried out for 30 minutes at a temperature of 200° C. under an inert atmosphere (e.g. nitrogen atmosphere) on the Sn alloy tape 30. The annealing heat treatment was carried out for 30 minutes at a temperature of 800° C. under the inert atmosphere on the Nb tape 20.

Thereafter, the Sn alloy tape 30 and the Nb tape 20 were overlapped and wound together around an outer periphery of the core material 10 in several turns. In more concrete, each of the Sn alloy tape 30 and the Nb tape 20 was wound around the outer periphery of the core material 10 in 3.1 turns. The roll forming was carried out by passing the core material 10 through forming rolls 100 while winding the Sn alloy tape 30 and the Nb tape 20 around the core material 10, thereby manufacturing the inner wire 40 as the jelly roll wire rod.

Subsequently, as shown in FIG. 3, a Cu coil 50a, in which a Cu tape 50 (thickness of 40 μm and a width of 12 mm) was wound around a predetermined core, was prepared. The inner wire 40 was coated with the Cu tape 50 at its outer periphery, namely, the Cu tape 50 was wound around the inner wire 40 in 1.7 turns, and molded by the roll forming to have a substantially hexagonal cross section. According to this process, a wire rod 60 as the first wire rod was obtained. As shown in FIG. 4, the wire rod 60 was a hexagonal wire having a cross sectional area corresponding to that of a circle with a diameter of 2.2 mm. Herein, the annealing heat treatment was previously carried out for a predetermined time at a predetermined temperature under a predetermined atmosphere on the Cu tape 50. To be concrete, the annealing heat treatment was carried out for 30 minutes at a temperature of 400° C. under the inert atmosphere on the Cu tape 50.

Next, the wire rod 60 was redressed, and cut with every length of 250 mm. Subsequently, as shown in FIG. 5, the cut wire rods 60 and a barrier layer 80 were incorporated into a billet 70 for multi-wires comprising a copper (a diameter of 78 mm and a thickness of 4 mm), to provide a multi billet 65. Herein, a Ta tape with a thickness of 1 mm was used as the barrier layer 80 incorporated between the billet 70 for multi-wires and the wire rods 60. The number of pieces of the wire rod 60 incorporated in the billet 70 for multi-wires was 1089.

Subsequently, the multi billet 65 was extruded by the cold extrusion to provide a wire as an extruded material with a diameter of 30 mm. In this Example, the cold extrusion could be conducted under a low cold extruding pressure, in which the Sn alloy composing the wire rod 60 does not melt by the processing heat generated in the extruding processing.

Next, the drawing processing was carried out on the extruded material, thereby manufacturing a drawn material with a diameter of 1.5 mm. Subsequently, a heat treatment for 200 to 300 hours at a temperature of 650 to 750° C. was carried out on the drawn material. After the heat treatment, Cu as the stabilizer was coated on an outer periphery of the drawn material after the heat treatment, thereby manufacturing the superconducting wire in the Example 1.

Superconducting characteristics of the superconducting wire in the Example 1 that was fabricated as described above were measured at a temperature of 4.2K. As a result, a non-copper critical current density (non-Cu Jc) was 3100 A/mm² (at 12 T).

### Example 2

In Example 2 of the present invention, Nb₃Al was used as the material composing the superconducting wire. The superconducting wire in the Example 2 was fabricated by the manufacturing process similar to that of the superconducting wire in the Example 1. Therefore, detailed description thereof is omitted except dissimilarities.

In the Example 2, an Al tape (thickness of 50 μm and a width of 23 mm) as the first metallic thin film tape and a Nb tape (thickness of 100 μm and a width of 23 mm) as the second metallic thin film tape were wound around a core material (a Nb wire with a diameter of 0.8 mm) in 4.5 turns similarly to the Example 1. A cross section thereof was formed to have a substantially hexagonal shape by the roll forming. The wire rod in the Example 2 was a hexagonal wire corresponding to that of a circle with a diameter of 2.3 mm.

Next, the wire rod was redressed, and cut with every length of 500 mm. Subsequently, the cut first wire rods and a barrier layer of Ta were incorporated into a large diameter billet for multi-wires comprising a copper (a diameter of 160 mm and a thickness of 10 mm), to provide a multi billet. Herein, the number of the cut pieces of the first wire rod incorporated in the large diameter billet for multi-wires was 3050.

Subsequently, the multi billet was extruded by the cold extrusion to provide a wire as an extruded material with a diameter of 50 mm. Next, the drawing processing was carried out on the extruded material, thereby manufacturing a drawn material with a diameter of 1.5 mm. In the Example 2, the large diameter billet for multi-wires comprising the copper that is coated on the outer periphery of the drawn material was removed by using a nitric acid. Thereafter, the rapid heating quenching treatment was carried out on the drawn material after removing the copper, thereby manufacturing the superconducting wire in the Example 2.

Superconducting characteristics of the superconducting wire in the Example 2 that was fabricated as described above were measured at the temperature of 4.2K. As a result, the non-copper critical current density (non-Cu Jc) was 2500 A/mm² (at 12 T).

### Example 3

In Example 3 of the present invention, NbTi was used as the material composing the superconducting wire. The superconducting wire in the Example 3 was fabricated by the manufacturing process similar to that of the superconducting wire in the Example 1. Therefore, detailed description thereof is omitted except dissimilarities.

In the Example 3, a NbTi wire with a diameter of 1.75 mm was used as the core material. As the metallic thin film tape, only a Cu tape (thickness of 70 μm and a width of 8.5 mm) was used. The Cu tape was wound around the core material in 2 turns, and processed by the roll forming. In other words, the Cu tape was wound around the core material and processed to have a circular cross section, and an area reduction processing was carried out thereon to have a hexagonal cross section. Further, a cassette roll drawing was carried out, thereby manufacturing a hexagonal wire as the first wire rod with a copper volume ratio of 0.33 and a cross sectional area corresponding to that of a circle with a diameter of φ1.5 mm. Herein, the Cu tape comprises an oxygen-free copper.

Next, the hexagonal wire was redressed, and cut with every length of 250 mm. Subsequently, cut pieces of the hexagonal wire were incorporated into a billet for multi-wires comprising a copper (a diameter of 76 mm and a thickness of 5 mm), to provide a multi billet. Herein, the number of the cut pieces of the hexagonal wire incorporated in the billet for multi-wires was 1930.

Subsequently, the multi billet was extruded at a temperature of 300° C. to provide an extruded material with a diameter of 27 mm. Next, the drawing processing was carried out on the extruded material, and aging heat treatment was carried out for several times during the drawing processing, thereby manufacturing the superconducting wire with a copper volume ratio of 0.75. The superconducting wire includes the hexagonal wires each having a diameter of 16 μm, and an outer diameter of the superconducting wire was 0.8 mm.

Superconducting characteristics of the superconducting wire in the Example 3 that was fabricated as described above were measured at the temperature of 4.2K. As a result, the non-copper critical current density (non-Cu Jc) was 1200 A/mm² (at 12 T).

Although the invention has been described with respect to the specific embodiments for complete and clear disclosure, the appended claims are not to be therefore limited but are to be construed as embodying all modifications and alternative constructions that may occur to one skilled in the art which fairly fall within the basic teaching herein set forth.

What is claimed is:

1. A method for fabricating a superconducting wire, comprising:
winding a metallic thin film around a core material comprising a first metallic material in a predetermined number of windings to provide a first wire rod having a diameter which is applicable for roll forming in a longitudinal direction of the core material, the metallic thin film being formed by rolling a second metallic material and carrying out an annealing heat treatment on the rolled second metallic material;
cutting the first wire rod to provide second wire rods;
filling the second wire rods into a billet for multi-wires to provide a multi billet;
extruding the multi billet to provide an extruded material;
drawing the extruded material to provide a drawn material; and
carrying out a heat treatment on the drawn material to provide the superconducting wire.

2. The method for fabricating a superconducting wire according to claim 1, wherein the superconducting wire comprises Nb compound or Nb alloy,
wherein the first metallic material comprises at least one metallic material selected from a group consisted of Nb, Nb alloy, Ta, Cu, Sn and Sn alloy,
wherein the second metallic material comprises at least one metallic material selected from a group consisted of Nb, Sn, Sn alloy, Al and Cu,
wherein the first metallic material comprises a material containing a first metal component composing the Nb compound, and a second metal component which forms the Nb compound by being bonded to the first metal component is selected from components of the Nb compound as the second metallic material.

3. The method for fabricating a superconducting wire according to claim 1, wherein the superconducting wire comprises Nb compound or Nb alloy,
wherein the first metallic material comprises at least one metallic material selected from a group consisted of Nb, Nb alloy, Ta, Cu, Sn and Sn alloy,
wherein the second metallic material comprises at least one metallic material selected from a group consisted of Nb, Sn, Sn alloy, Al and Cu,
wherein the first metallic material comprises a material which does not contain first metal component composing the Nb compound, and both of the first metal component and the second metal component which forms the Nb compound by being bonded to the first metal component are selected from components of the Nb compound as the second metallic material.

4. The method for fabricating a superconducting wire according to claim 3, wherein the metallic thin film tape comprises a first tape comprising the first metal component and a second tape comprising the second metal component,
wherein the first tape and the second tape are wound together around the core.

5. The method for fabricating a superconducting wire according to claim 3, wherein the metallic thin film tape comprises a composite tape of a first tape comprising the first metal component and a second tape comprising the second metal component.

6. The method for fabricating a superconducting wire according to claim 2, wherein the number of the second wire rods filled into the multi billet is 1000 or more.

7. The method for fabricating a superconducting wire according to claim 3, wherein the number of the second wire rods filled into the multi billet is 1000 or more.

8. The method for fabricating a superconducting wire according to claim 4, wherein the predetermined number of windings is 1.2 to 6 turns around the core material.

9. The method for fabricating a superconducting wire according to claim 1, wherein the second wire rods are filled within a range of 0.2 to 0.4 pieces/mm² for a cross section of the billet for multi-wires.
